(19) United States
(12) Patent Application Publication
(10) Pub. No.: US 2020/0006643 A1
(43) Pub. Date: Jan. 2, 2020

(54) INTEGRATION OF TOP SPIN ORBIT ELECTRODE IN MAGNETIC RANDOM ACCESS MEMORY DEVICES USING ATOMIC LATER ETCHING

(71) Applicant: Intel Corporation, Santa Clara, CA (US)

(72) Inventors: Tanay GOSAVI, Hillsboro, OR (US); Sasikanth MANIPATRUNI, Portland, OR (US); Chia-Ching LIN, Portland, OR (US); Gary ALLEN, Portland, OR (US); Scott B. CLENDENING, Portland, OR (US); Ian YOUNG, Portland, OR (US)

(21) Appl. No.: 16/024,712

(22) Filed: Jun. 29, 2018

(51) Int. Cl. H01L 43/12; H01L 43/02; H01F 10/32; H01F 41/34; G11C 11/16; H01L 27/22

(52) U.S. Cl. CPC H01L 43/12; H01L 43/02; H01F 10/3254; H01F 10/3286; H01L 43/10; H01F 41/34; G11C 11/161; H01L 27/222; H01F 10/3272

(57) ABSTRACT

Embodiments herein relate to manufacturing a magnetic random access memory (MRAM). In particular, a process may include coupling a side of a magnetic free layer of a magnetic tunnel junction (MTJ) to a first side of a hybrid spin orbit torque (SOT) electrode-insert layer, coupling a first side of an atomic layer etching (ALE) etch layer to a second side of the hybrid SOT electrode-insert layer opposite the first side, applying an interlayer dielectric (ILD) layer to edges of the MTJ, the SOT electrode and the etch layers, the ILD layer in a plane substantially perpendicular to a plane of the MTJ, SOT electrode and ALE etch layers, and etching the ALE etch layer using ALE until the SOT layer is exposed.

### FIELD

Embodiments of the present disclosure generally relate to the field of magnetic random access memory (MRAM), and in particular the use of atomic layer etching (ALE) to couple a magnetic tunnel junction (MTJ) and a spin orbit torque (SOT) electrode.

### BACKGROUND

The background description provided herein is for the purpose of generally presenting the context of the disclosure. Unless otherwise indicated herein, the materials described in this section are not prior art to the claims in this application and are not admitted to be prior art by inclusion in this section.

For in-plane polarized magnetic films, electron spin currents arising from the spin-Hall effect (SHE) within heavy metal has been shown to apply spin-transfer torques to a magnet. The SHE may be used to change a magnetic polarity of a free layer of a magnetic tunnel junction (MTJ) that may be used to implement MRAM.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 illustrates a stage during the manufacture of a MRAM stack with a MTJ that includes a hybrid SOT electrode-insert layer and an ALE etch layer, in accordance with one implementation of the invention.

FIG. 2 illustrates a stage during the manufacture of a MRAM stack with a MTJ that includes an inter-layer dielectric (ILD), in accordance with one implementation of the invention.

FIG. 3 illustrates a stage during the manufacture of a MRAM stack with a MTJ that includes an ALE process to expose a hybrid SOT electrode-insert layer, in accordance with one implementation of the invention.

FIG. 4 illustrates a stage during the manufacture of a MRAM stack with a MTJ that includes a SOT electrode, in accordance with one implementation of the invention.

FIG. 5 illustrates an example process for using ALE during the manufacture of a MRAM stack, in accordance with one implementation of the invention.

FIG. 6 shows a complimentary metal-oxide-semiconductor (CMOS) stack that integrates an MRAM, in accordance with various embodiments.

FIG. 7 illustrates a computing device 700 in accordance with one implementation of the invention.

FIG. 8 illustrates an interposer 800 that includes one or more embodiments of the invention.

### DETAILED DESCRIPTION

Embodiments of the present disclosure generally relate to apparatuses, processes, or systems to manufacture or to use MRAM. In legacy implementations, the MRAM may include a SOT electrode that may include a heavy metal, 2D material, Antiferromagnet (AFM) or topological insulator (TI). The SOT electrode may facilitate switching the magnetic field within a magnetic free layer of a MTJ magnetically coupled to the SOT electrode by changing the polarity direction of the magnetic field in the magnetic free layer of the MTJ.

The SOT may enable use of complex magnetic stacks that may be developed with a bottom synthetic antiferromagnet (SAF) to implement spin transfer torque memory. In legacy implementations, during MRAM manufacture there may be patterning and integration challenges, such as patterning a top SOT electrode on a MRAM nanopillar that has an atomically clean interface. Other challenges may include engineering the SOT electrode to avoid a shunt current path that may degrade MRAM efficiency.

Legacy implementations may use a differential rate of a chemical mechanical processing (CMP) polishing rate for patterning the top electrode with respect to a spacer layer. These implementations may result in difficulty getting an interconnect on both sides of the SOT electrode. The limited choices in CMP combined with wafer scale variation in CMP processing may make it difficult in legacy implementations to produce a thin SOT electrode with repeatable thickness for an SOT across the wafer. Difficulties getting a uniform thicknesses across the wafer, and the variation in SOT thickness between dies can result in a large varience in the operating voltages of the SOTs. In addition, legacy manufacturing processes may rely on deposition of an additional top SOT and may depend on current spreading. As a result, this legacy approach may limit the efficacy of the SOT devices, and may limit the set of materials that may be used for the SOT electrode. For example, this may limit the use of topological insulators (TI) in the SOT electrode.

Embodiments disclosed herein may be directed to using ALE for fabricating a top SOT electrode in an MRAM stack. ALE may be used to etch away an etch layer, leaving behind a clean interface of a hybrid SOT electrode-insert layer onto which a new SOT electrode may be patterned, for example by liftoff or subtractive process

ALE may rely on layer by layer chemical processing by oxidation or chlorination of materials and then etching them away. The etching process may leave atomically clean interfaces, which may greatly facilitate subsequent depositing of SOT material for use as an SOT electrode that may be used to switch an MTJ. For proper operation of the MTJ, an atomically smooth interface between the free layer of the MTJ and the SOT electrode may be very important to facilitate the electron spin that may need to be injected in the MTJ free layer.

In embodiments, a hybrid SOT electrode-insert layer may be placed between the top SOT electrode and the free layer of the MTJ. The hybrid SOT electrode-insert layer may help keep the free layer and SOT electrode layer interface clean. It may also provide more flexibility for choosing an etch chemistry for the ALE. The hybrid SOT electrode-insert layer may also reduce interface losses by reducing Dzyaloshinskii-Moriya interaction (DMI) and facilitating electron spin for efficient coupling with the free layer.

In embodiments, hybrid SOT electrode-insert layer materials may include, but are not limited to, Hf, W, Cu, Au, Ir, Ta, Gd, and the like. The materials used may depend on the materials used for the SOT electrode. The hybrid SOT electrode-insert layer may be thin, for example but not limited to sub 2 nanometers, so that the hybrid SOT electrode-insert layer may allow electron spins to flow through it without absorbing the spins and decoupling the interface of SOT electrode and the free layer.

In embodiments, any material with a high spin orbit coupling may be used for the SOT in the MRAM. Thus, due to the use of the ALE process, the of SOT materials for use may not be limited by the use of chemical mechanical processing (CMP) during manufacture.

In the following detailed description, reference is made to the accompanying drawings which form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

Various operations may be described as multiple discrete operations in turn, in a manner that is most helpful in understanding the claimed subject matter. However, the order of description should not be construed as to imply that these operations are necessarily order dependent.

As used herein, the term “module” may refer to, be part of, or include an application specific integrated circuit (ASIC), an electronic circuit, a processor (shared, dedicated, or group) and/or memory (shared, dedicated, or group) that execute one or more software or firmware programs, a combinational logic circuit, and/or other suitable components that provide the described functionality.

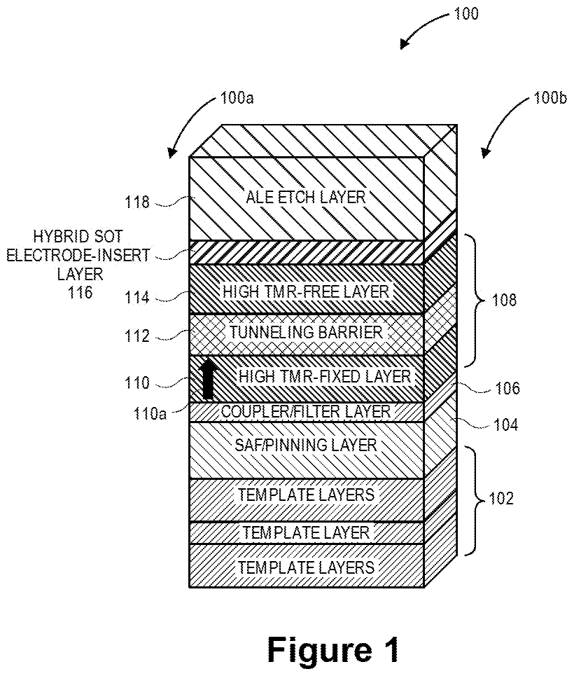

FIG. 1 illustrates a stage during the manufacture of a MRAM stack with a MTJ that includes a hybrid SOT electrode-insert layer and an ALE etch layer, in accordance with one implementation of the invention. Diagram 100 shows a partial MRAM stack that may include template layers 102 that may be coupled to a synthetic anti-Ferro-magnet (SAF) layer 104. In embodiments the SAF layer 104 may cancel the dipole fields around other layers within the MRAM stack 100. In embodiments, a coupler/filter layer 106 may be coupled to the SAF layer 104. In embodiments, an MTJ 108 may be coupled to the coupler/filter layer 106.

In embodiments, the MTJ 108 may include a magnetic fixed layer 110 that may have a fixed magnetic polarity 110a. In embodiments, the magnetic fixed layer 110 may be a high tunnel magnetoresistance (TMR) layer. In embodiments, the high TMR layer may be implemented by one or more Ferromagnetic layer. In embodiments, the magnetic fixed layer 110 may be complex and made of multiple ferromagnets (not shown) coupled with an antiferromagnetic or ferromagnetic coupling layer (not shown) between them. The materials for a coupling layer (not shown) may include, but are not limited to, Ru, Ir, Gd, W, Ta, CoW, and the like, and may be used to achieve perpendicular magnetic fields and to improve efficiency of magnetic polarity switching of the magnetic free layer 114. A tunneling barrier 112, that in embodiments may include a MgO tunneling oxide, may separate the magnetic fixed layer 110 from the magnetic free layer 114. In embodiments, the magnetic free layer 114 may be a high TMR layer. In embodiments, the high TMR layer may be implemented by one or more Ferromagnetic layer. The fixed layer 110, tunneling barrier 112, and magnetic free layer 114 may make up the MTJ 108.

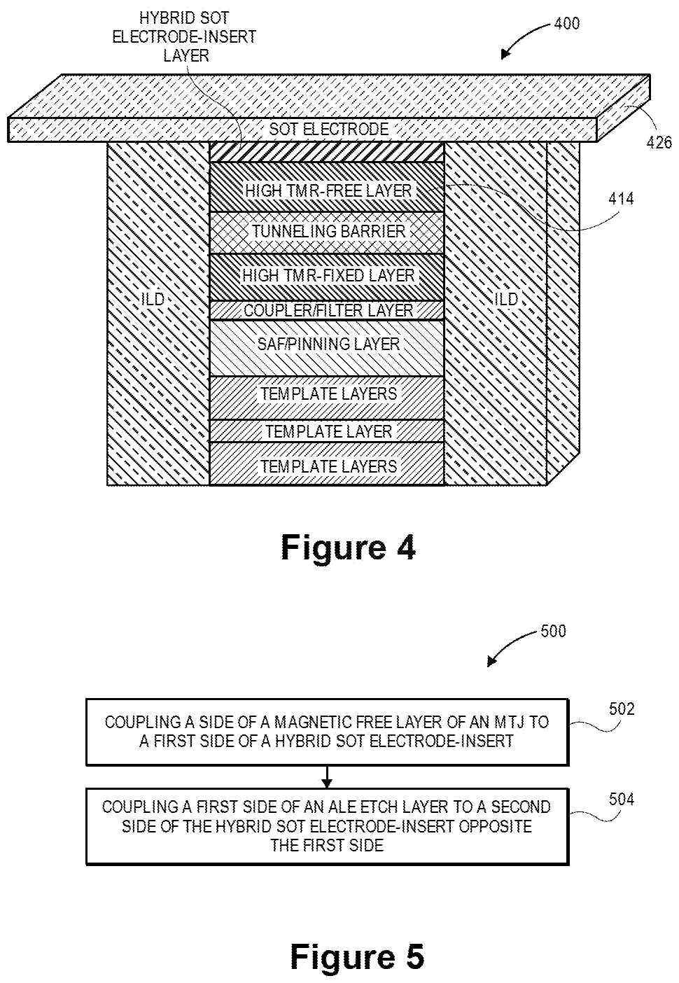

A hybrid SOT electrode-insert layer 116 may be coupled to the magnetic free layer 114. In embodiments, the hybrid SOT electrode-insert layer 116 may allow for efficient transmission of the spin polarized electrons to the magnetic free layer 114 by reducing electron spin reflection. It may also reduce DMI with the magnetic free layer 114. Using the hybrid SOT electrode-insert layer 116 in the MRAM creation process may keep the interface between an SOT electrode, such as SOT electrode 426 of FIG. 4, and the magnetic free layer 114 very clean to allow electron spins to diffuse into the magnetic free layer 114 from SOT electrode 426. The hybrid SOT electrode-insert layer 116 may have additional advantage of decoupling DMI at the interface which may increase the efficiency of the MRAM switching by changing the current direction flowing through the SOT electrode 426. In embodiments, a thickness of a SOT electrode 426 may be greater than 3-4 nm and may generate electron spins when current is passed through it. A hybrid SOT electrode-insert layer 116, may be, but is not limited to 1-2 nm, and may only allow electron spin to slow without absorption as the electron spin is passed through the hybrid SOT electrode-insert layer 116. The hybrid SOT electrode-insert layer 116 may also reduce spin reflection and improve spin transfer efficiency. In embodiments, an ALE etch layer 118 may be coupled to the hybrid SOT electrode-insert layer 116.

In embodiments, the partial MRAM stack 100 may be etched, for example on sides 100a, 100b to form a nano pillar. In embodiments, the etching process may include ion beam etching (IBE) or reactive ion etching (ME).

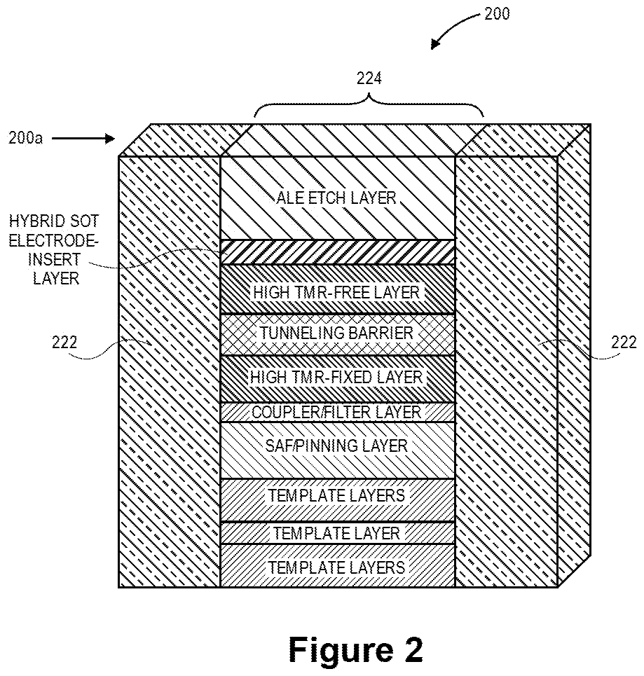

FIG. 2 illustrates a stage during the manufacture of a MRAM stack with a MTJ that includes an inter-layer dielectric (ILD), in accordance with one implementation of the invention. Diagram 200 shows a partial MRAM stack that has an ILD 222 coupled to all or part of the nano pillar 224, which may be similar to the partial MRAM stack of diagram 100 of FIG. 1.

In embodiments, after the ILD 222 has been coupled to the nano pillar 224, a process may be used to planarize a top 200a of the MRAM stack 200. In embodiments, this process may include all or part of a CM′ process. The planarization may be to prepare MRAM stack 200 for a subsequent ALE process.

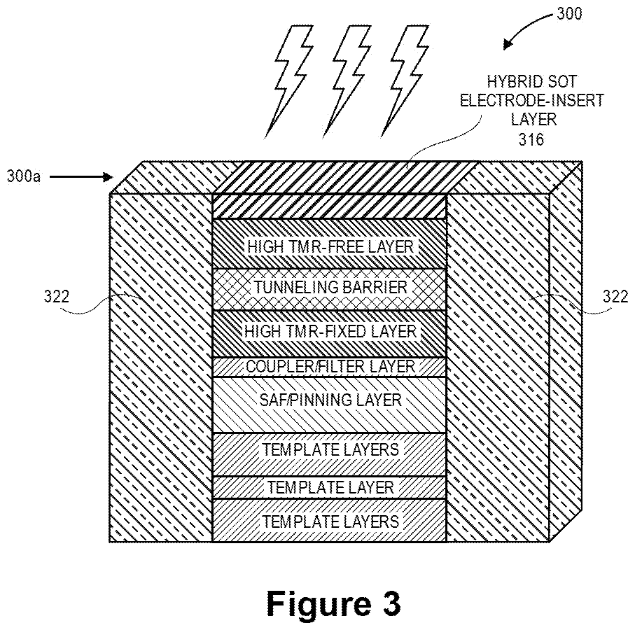

FIG. 3 illustrates a stage during the manufacture of a MRAM stack with a MTJ that includes an ALE process to expose the hybrid SOT electrode-insert layer, in accordance with one implementation of the invention. Diagram 300 shows a partial MRAM stack after an ALE process to expose a top layer 300a of the MRAM stack 300 that may expose the hybrid SOT electrode-insert layer 316, which may be similar to the hybrid SOT electrode-insert layer 116 of FIG. 1. In embodiments, the ALE etch layer, which may be similar to ALE etch layer 118 of FIG. 1, may be removed, as well as portions of the ILD 322, which may be similar to the ILD 222 of FIG. 2.

A result of the ALE process may be to leave behind an atomically clean interface at the top of the hybrid SOT electrode-insert layer 316. This may then facilitate depositing and patterning of an SOT metal.

FIG. 4 illustrates a stage during the manufacture of a MRAM stack with a MTJ that includes a SOT electrode, in accordance with one implementation of the invention. Diagram 400 shows an MRAM stack with a SOT electrode 426 deposited on the surface 300a of FIG. 3. In embodiments, the SOT electrode 426 may subsequently be patterned.

In embodiments, the composition of the SOT electrode 426 may include one or more heavy metals, AFM, or topological insulator (TI). In embodiments, SOT electrode 426 may include spin orbit TI, 2D or 3D materials which may include, but are not limited to, one or more of: graphene, TiSe₂, WSe₂, MoS₂, WSe₂, MoSe₂, B₂S₃, Sb₂S₃, Ta₂S, Re₂S₇, LaCPS₂, LaOAsS₂, ScOBiS₂, GaOBiS₂, AlOBiS₂, LaOSbS₂, BiOBiS₂, YOBiS₂, InOBiS₂, LaOBiSe₂, TiOBiS₂, CeOBiS₂, PrOBiS₂, NdOBiS₂, LaOBiS₂, or SrFBiS₂. In embodiments, SOT electrode 426 may include spin orbit material that may exhibit a Rashba-Bychkov effect in the form ROCh₂, where ‘It’ includes, but is not limited to, one or more of: La, Ce, Pr, Nd, Sr, Sc, Ga, Al, or In, and where “Ch” may be a chalcogenide which may include, but is not limited to, one or more of: S, Se, or Te.

An AFM may include, but is not limited to, Co/Antiferro-magnet, Fe/Antiferro-magnet, Ni/Antiferro-magnet, MnGa/Antiferro-magnet, MnGeGa/Antiferro-magnet, or Bct-Ru/Antiferro-magnet. A TI may also include, but is not limited to, Bi₂Se₃, BiₓTe_{y}Se_{1-x-y}, BiₓSb₁₋ₓ, WSe₂, WTe₂, PtSe₂, PtTe₂, MoSe₂, MoS₂, or MoTe₂, TiS₂, WS₂, TiSe₂, B₂₅₃, Sb₂S₃, Ta₂S, Re₂S₇, LaCPS₂, LaOAsS₂, ScOBiS₂, GaOBiS₂, AlOBiS₂, LaOSbS₂, BiOBiS₂, YOBiS₂, InOBiS₂, LaOBiSe₂, TiOBiS₂, CeOBiS₂, PrOBiS₂, NdOBiS₂, LaOBiS₂, or SrFBiS₂.

In embodiments, the SOT electrode 426 may be magnetically doped using magnetic material (not shown) that may include, but is not limited to, ferromagnets such as cobolt (Co), iron (Fe), nickel (Ni), MnGa, MnGeGa, Bct-Ru, Gd, or Tb. Magnetic material (not shown) may include material with perpendicular magnetic anisotropy (PMA) with an anisotropy axis perpendicular to a plane of the SOT electrode 426.

As a result, the SOT electrode 426 may have a net magnetic moment that may interact with the adjacent magnetic free layer, such as magnetic free layer 414, which may be similar to magnetic free layer 114 of FIG. 1. As a result, this may apply an effective field on the free layer magnet in a direction opposite to the internal magnetic moment. This effective field may then break the symmetry of the spin orbit switching of the free layer, thereby enabling repeatable bidirectional current switching. The doped SOT electrode 426 layer may create an inplane exchange bias or a dipole field. This resulting effective field may generate an inplane magnetic field on the perpendicular magnetic free layer of the MTJ. This may then facilitate deterministic bi-directional switching of the MRAM by flipping the polarity of the magnetic free layer 414 depending on the direction of current flow through the SOT electrode 426. This may enable repeatable bidirectional switching of a perpendicular magnetic polarity within magnetic free layers such as magnetic free layer 414 within the MRAM.

FIG. 5 illustrates an example process for using ALE during the manufacture of a MRAM stack, in accordance with one implementation of the invention. Process 500 may be used to manufacture an MRAM stack using ALE.

At block 502, the process may include coupling a side of a magnetic free layer of an MTJ to a first side of a hybrid SOT electrode-insert layer. As shown in FIG. 1, the magnetic free layer 114, that may be part of the MTJ 108, may be coupled with a first side of a hybrid SOT electrode-insert layer 116. In embodiments, the hybrid SOT electrode-insert layer 116 may be applied as a part of a buildup process.

At block 504, the process may include coupling a first side of an ALE etch layer to a second side of the hybrid SOT/insert layer opposite the first side. As shown in FIG. 1, the ALE etch layer 118 may be coupled with the hybrid SOT electrode-insert layer 116. In embodiments, the ALE etch layer 118 may be applied as a part of a buildup process.

The process may further include etching, using ALE, the etch layer to expose the second side of the hybrid SOT electrode-insert layer 116. As shown in FIG. 3, an ALE process has been used to etch a surface 300a exposing the hybrid SOT electrode-insert layer 316. In embodiments, the hybrid SOT electrode-insert layer 316 may be atomically very clean, which may facilitate efficient transmission of the spin polarized electrons to a magnetic free layer by reducing the spin reflection from a SOT layer, such as SOT electrode 426 of FIG. 4, that may be coupled to the etched hybrid SOT electrode-insert layer 316.

Implementations of embodiments of the invention may be formed or carried out on a substrate, such as a semiconductor substrate. In one implementation, the semiconductor substrate may be a crystalline substrate formed using a bulk silicon or a silicon-on-insulator substructure. In other implementations, the semiconductor substrate may be formed using alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of group III-V or group IV materials. Although a few examples of materials from which the substrate may be formed are described here, any material that may serve as a foundation upon which a semiconductor device may be built falls within the spirit and scope of the present invention.

A plurality of transistors, such as metal-oxide-semiconductor field-effect transistors (MOSFET or simply MOS transistors), may be fabricated on the substrate. In various implementations of the invention, the MOS transistors may be planar transistors, nonplanar transistors, or a combination of both. Nonplanar transistors include FinFET transistors such as double-gate transistors and tri-gate transistors, and wrap-around or all-around gate transistors such as nanoribbon and nanowire transistors. Although the implementations described herein may illustrate only planar transistors, it should be noted that the invention may also be carried out using nonplanar transistors.

Each MOS transistor includes a gate stack formed of at least two layers, a gate dielectric layer and a gate electrode layer. The gate dielectric layer may include one layer or a stack of layers. The one or more layers may include silicon oxide, silicon dioxide (SiO2) and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric layer include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric layer to improve its quality when a high-k material is used.

The gate electrode layer is formed on the gate dielectric layer and may consist of at least one P-type workfunction metal or N-type workfunction metal, depending on whether the transistor is to be a PMOS or an NMOS transistor. In some implementations, the gate electrode layer may consist of a stack of two or more metal layers, where one or more metal layers are workfunction metal layers and at least one metal layer is a fill metal layer.

For a PMOS transistor, metals that may be used for the gate electrode include, but are not limited to, ruthenium, palladium, platinum, cobalt, nickel, and conductive metal oxides, e.g., ruthenium oxide. A P-type metal layer will enable the formation of a PMOS gate electrode with a workfunction that is between about 4.9 eV and about 5.2 eV. For an NMOS transistor, metals that may be used for the gate electrode include, but are not limited to, hafnium, zirconium, titanium, tantalum, aluminum, alloys of these metals, and carbides of these metals such as hafnium carbide, zirconium carbide, titanium carbide, tantalum carbide, and aluminum carbide. An N-type metal layer will enable the formation of an NMOS gate electrode with a workfunction that is between about 3.9 eV and about 4.2 eV.

In some implementations, the gate electrode may consist of a “U”-shaped structure that includes a bottom portion substantially parallel to the surface of the substrate and two sidewall portions that are substantially perpendicular to the top surface of the substrate. In another implementation, at least one of the metal layers that form the gate electrode may simply be a planar layer that is substantially parallel to the top surface of the substrate and does not include sidewall portions substantially perpendicular to the top surface of the substrate. In further implementations of the invention, the gate electrode may consist of a combination of U-shaped structures and planar, non-U-shaped structures. For example, the gate electrode may consist of one or more U-shaped metal layers formed atop one or more planar, non-U-shaped layers.

In some implementations of the invention, a pair of sidewall spacers may be formed on opposing sides of the gate stack that bracket the gate stack. The sidewall spacers may be formed from a material such as silicon nitride, silicon oxide, silicon carbide, silicon nitride doped with carbon, and silicon oxynitride. Processes for forming sidewall spacers are well known in the art and generally include deposition and etching process steps. In an alternate implementation, a plurality of spacer pairs may be used, for instance, two pairs, three pairs, or four pairs of sidewall spacers may be formed on opposing sides of the gate stack.

As is well known in the art, source and drain regions are formed within the substrate adjacent to the gate stack of each MOS transistor. The source and drain regions are generally formed using either an implantation/diffusion process or an etching/deposition process. In the former process, dopants such as boron, aluminum, antimony, phosphorous, or arsenic may be ion-implanted into the substrate to form the source and drain regions. An annealing process that activates the dopants and causes them to diffuse further into the substrate typically follows the ion implantation process. In the latter process, the substrate may first be etched to form recesses at the locations of the source and drain regions. An epitaxial deposition process may then be carried out to fill the recesses with material that is used to fabricate the source and drain regions. In some implementations, the source and drain regions may be fabricated using a silicon alloy such as silicon germanium or silicon carbide. In some implementations the epitaxially deposited silicon alloy may be doped in situ with dopants such as boron, arsenic, or phosphorous. In further embodiments, the source and drain regions may be formed using one or more alternate semiconductor materials such as germanium or a group III-V material or alloy. And in further embodiments, one or more layers of metal and/or metal alloys may be used to form the source and drain regions.

One or more interlayer dielectrics (ILD) are deposited over the MOS transistors. The ILD layers may be formed using dielectric materials known for their applicability in integrated circuit structures, such as low-k dielectric materials. Examples of dielectric materials that may be used include, but are not limited to, silicon dioxide (SiO2), carbon doped oxide (CDO), silicon nitride, organic polymers such as perfluorocyclobutane or polytetrafluoroethylene, fluorosilicate glass (FSG), and organosilicates such as silsesquioxane, siloxane, or organosilicate glass. The ILD layers may include pores or air gaps to further reduce their dielectric constant.

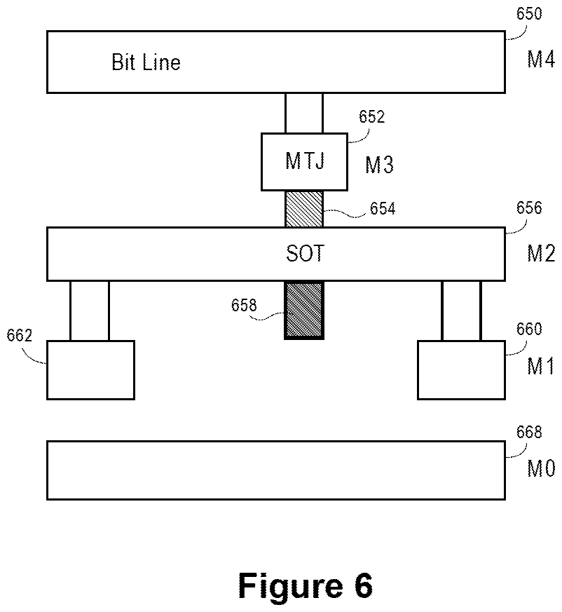

FIG. 6 shows a CMOS stack that integrates an MRAM, in accordance with various embodiments. The MTJ 652, which may be in metal layer 3, may be similar to MTJ 108 of FIG. 1, and may be coupled to the SOT 656, which may be in metal layer 2, and may be similar to SOT 426 of FIG. 4. Magnetic via 658 may include magnetically active material in the via 658 that may apply an in-plane magnetic field to a magnetic free layer of the MTJ 652. The magnetic free layer may be similar to magnetic free layer 114 of FIG. 1.

Sources for current flow through the SOT 656 may be through metal layer 1 via 662 and/or through metal layer 1 via 660. Bit line 650, which may be in metal layer 4, may provide current to the MTJ 652, that may be used to read a bit of the MRAM. Metal layer 0 668 may be at the bottom of the CMOS stack.

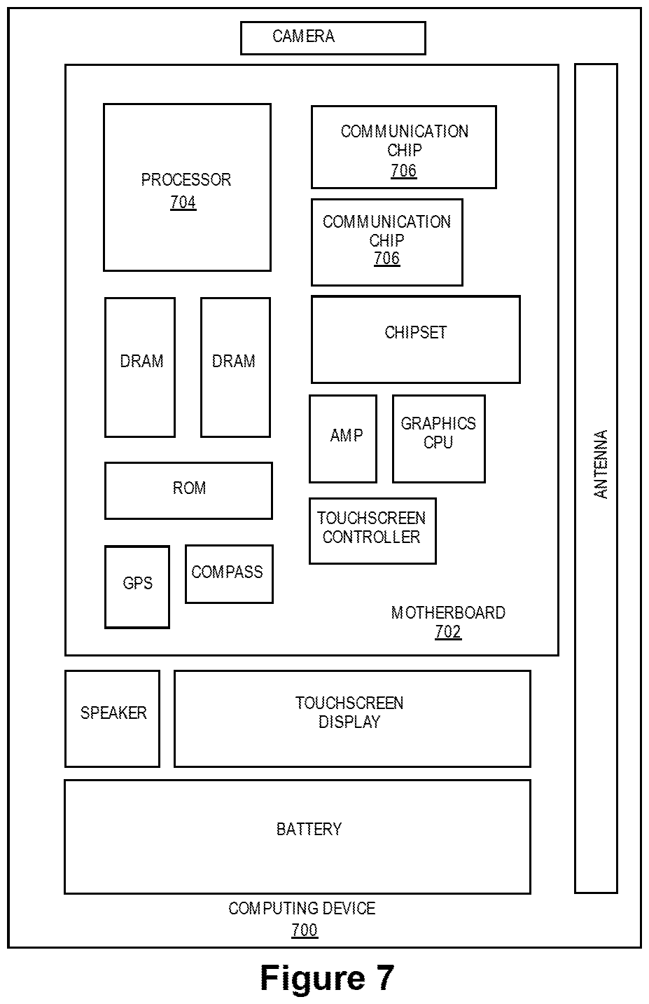

FIG. 7 illustrates a computing device 700 in accordance with one implementation of the invention. The computing device 700 houses a board 702. The board 702 may include a number of components, including but not limited to a processor 704 and at least one communication chip 706. The processor 704 is physically and electrically coupled to the board 702. In some implementations the at least one communication chip 706 is also physically and electrically coupled to the board 702. In further implementations, the communication chip 706 is part of the processor 704.

Depending on its applications, computing device 700 may include other components that may or may not be physically and electrically coupled to the board 702. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 706 enables wireless communications for the transfer of data to and from the computing device 700. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 706 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 600 may include a plurality of communication chips 706. For instance, a first communication chip 606 may be dedicated to shorter range wireless communications such as Wi-Fi and Bluetooth and a second communication chip 706 may be dedicated to longer range wireless communications such as GPS, EDGE, GPRS, CDMA, WiMAX, LTE, Ev-DO, and others.

The processor 704 of the computing device 700 includes an integrated circuit die packaged within the processor 704. In some implementations of the invention, the integrated circuit die of the processor includes one or more devices, such as MOS-FET transistors built in accordance with implementations of the invention. The term “processor” may refer to any device or portion of a device that processes electronic data from registers and/or memory to transform that electronic data into other electronic data that may be stored in registers and/or memory.

The communication chip 706 also includes an integrated circuit die packaged within the communication chip 706. In accordance with another implementation of the invention, the integrated circuit die of the communication chip includes one or more devices, such as MOS-FET transistors built in accordance with implementations of the invention.

In further implementations, another component housed within the computing device 700 may contain an integrated circuit die that includes one or more devices, such as MOS-FET transistors built in accordance with implementations of the invention.

In various implementations, the computing device 700 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 700 may be any other electronic device that processes data.

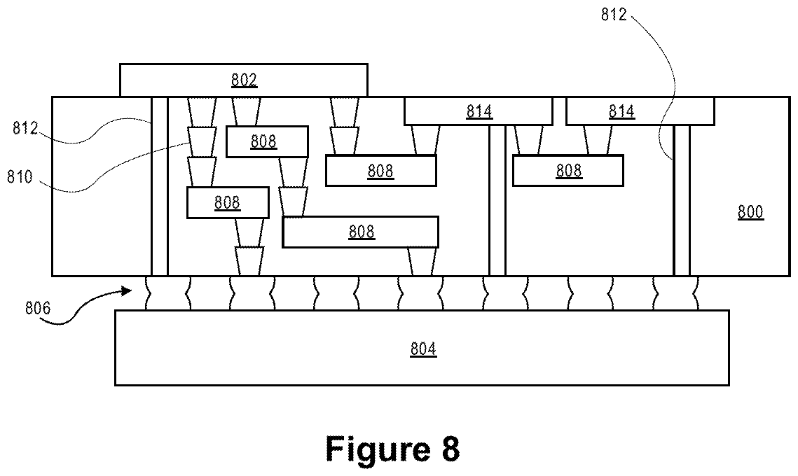

FIG. 8 illustrates an interposer 800 that includes one or more embodiments of the invention. The interposer 800 is an intervening substrate used to bridge a first substrate 802 to a second substrate 804. The first substrate 802 may be, for instance, an integrated circuit die. The second substrate 804 may be, for instance, a memory module, a computer motherboard, or another integrated circuit die. Generally, the purpose of an interposer 800 is to spread a connection to a wider pitch or to reroute a connection to a different connection. For example, an interposer 800 may couple an integrated circuit die to a ball grid array (BGA) 806 that can subsequently be coupled to the second substrate 804. In some embodiments, the first and second substrates 802/804 are attached to opposing sides of the interposer 800. In other embodiments, the first and second substrates 802/804 are attached to the same side of the interposer 800. And in further embodiments, three or more substrates are interconnected by way of the interposer 800.

The interposer 800 may be formed of an epoxy resin, a fiberglass-reinforced epoxy resin, a ceramic material, or a polymer material such as polyimide. In further implementations, the interposer may be formed of alternate rigid or flexible materials that may include the same materials described above for use in a semiconductor substrate, such as silicon, germanium, and other group III-V and group IV materials.

The interposer may include metal interconnects 808 and vias 810, including but not limited to through-silicon vias (TSVs) 812. The interposer 800 may further include embedded devices 814, including both passive and active devices. Such devices include, but are not limited to, capacitors, decoupling capacitors, resistors, inductors, fuses, diodes, transformers, sensors, and electrostatic discharge (ESD) devices. More complex devices such as radio-frequency (RF) devices, power amplifiers, power management devices, antennas, arrays, sensors, and MEMS devices may also be formed on the interposer 800. In accordance with embodiments of the invention, apparatuses or processes disclosed herein may be used in the fabrication of interposer 800.

### EXAMPLES

Example 1 may be an apparatus comprising: a SOT electrode; a first side of an insert layer coupled to a side of the SOT electrode; a first side of a free layer of a MTJ coupled to a second side of the insert layer opposite the first side of the insert layer.

Example 2 may include the apparatus of example 1, wherein the insert layer is to reduce DMI at an interface of the SOT electrode and the free layer.

Example 3 may include the apparatus of example 1, wherein the insert layer is to reduce spin reflection to allow for efficient transmission of spin polarized electrons.

Example 4 may include the apparatus of example 1, wherein the free layer is a TMR-free layer.

Example 5 may include the apparatus of example 1, further comprising; a first side of a tunneling barrier of a MTJ coupled to a second side of the MTJ free layer opposite the first side; and a first side of a fixed layer of a MTJ coupled to a second side of the MTJ tunneling barrier opposite the first side.

Example 6 may include the apparatus of example 5, wherein the fixed layer of the MTJ is a TMR-fixed layer.

Example 7 may include the apparatus of example 1, wherein the first side of the free layer of the MTJ is a first side of the MTJ; and further comprising a first side of a filter layer coupled with a second side of the MTJ opposite the first side of the MTJ.

Example 8 may include the apparatus of any one of examples 1-7, further comprising: a first side of a synthetic anti-ferro magnet (SAF) coupled with a second side of the filter layer opposite the first side of the filter layer.

Example 9 may be a method comprising: coupling a side of a magnetic free layer of a magnetic tunnel junction (MTJ) to a first side of a hybrid spin orbit torque (SOT) electrode-insert layer; and coupling a first side of an atomic layer etching (ALE) etch layer to a second side of the hybrid SOT electrode-insert layer opposite the first side.

Example 10 may include the method of example 9, further comprising applying an ILD layer to edges of the MTJ, the SOT electrode and the ALE etch layers, wherein the ILD layer is in a plane substantially perpendicular to a plane of the MTJ, SOT electrode and etch layers.

Example 11 may include the method of example 10, further comprising etching the ALE etch layer using ALE until the SOT electrode-insert layer is exposed.

Example 12 may include the method of example 11, further comprising, after applying the ILD layer, planarizing a second side of the etch layer and a first edge of the ILD layer.

Example 13 may include the method of example 12, wherein planarizing further includes CMP.

Example 14 may include the method of any one of examples 9-12, further comprising coupling a first side of a SOT layer to the exposed SOT electrode-insert layer.

Example 15 may include the method of example 12, further comprising removing the ILD layer.

Example 16 may be an apparatus comprising: means for coupling a side of a magnetic free layer of a MTJ to a first side of a hybrid SOT electrode-insert layer; and means for coupling a first side of an ALE etch layer to a second side of the hybrid SOT electrode-insert layer opposite the first side.

Example 17 may include the apparatus of example 16, further comprising means for applying an ILD layer to edges of the MTJ, the SOT electrode and the ALE etch layers, wherein the ILD layer is in a plane substantially perpendicular to a plane of the MTJ, SOT electrode and etch layers.

Example 18 may include the apparatus of example 17, further comprising means for etching the ALE etch layer using ALE until the SOT electrode-insert layer is exposed.

Example 19 may include the apparatus of example 18, further comprising means for planarizing a second side of the etch layer and a first edge of the ILD layer.

Example 20 may include the apparatus of example 19, further comprising coupling a first side of a SOT layer to the exposed SOT electrode-insert layer.

Various embodiments may include any suitable combination of the above-described embodiments including alternative (or) embodiments of embodiments that are described in conjunctive form (and) above (e.g., the “and” may be “and/or”). Furthermore, some embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

The above description of illustrated embodiments, including what is described in the Abstract, is not intended to be exhaustive or to limit embodiments to the precise forms disclosed. While specific embodiments are described herein for illustrative purposes, various equivalent modifications are possible within the scope of the embodiments, as those skilled in the relevant art will recognize.

These modifications may be made to the embodiments in light of the above detailed description. The terms used in the following claims should not be construed to limit the embodiments to the specific implementations disclosed in the specification and the claims. Rather, the scope of the invention is to be determined entirely by the following claims, which are to be construed in accordance with established doctrines of claim interpretation.

What is claimed is:

1. An apparatus comprising:
a spin orbit torque (SOT) electrode;
a first side of an insert layer coupled to a side of the SOT electrode;
a first side of a free layer of a magnetic tunnel junction (MTJ) coupled to a second side of the insert layer opposite the first side of the insert layer.

2. The apparatus of claim 1, wherein the insert layer is to reduce Dzyaloshinskii-Moriya interaction (DMI) at an interface of the SOT electrode and the free layer.

3. The apparatus of claim 1, wherein the insert layer is to reduce spin reflection to allow for efficient transmission of spin polarized electrons.

4. The apparatus of claim 1, wherein the free layer is a tunnel magnetoresistive (TMR)-free layer.

5. The apparatus of claim 1, further comprising;
a first side of a tunneling barrier of a MTJ coupled to a second side of the MTJ free layer opposite the first side; and
a first side of a fixed layer of a MTJ coupled to a second side of the MTJ tunneling barrier opposite the first side.

6. The apparatus of claim 5, wherein the fixed layer of the MTJ is a TMR-fixed layer.

7. The apparatus of claim 1, wherein the first side of the free layer of the MTJ is a first side of the MTJ; and further comprising a first side of a filter layer coupled with a second side of the MTJ opposite the first side of the MTJ.

8. The apparatus of claim 7, further comprising:
a first side of a synthetic anti-ferro magnet (SAF) coupled with a second side of the filter layer opposite the first side of the filter layer.

9. A method comprising:
coupling a side of a magnetic free layer of a magnetic tunnel junction (MTJ) to a first side of a hybrid spin orbit torque (SOT) electrode-insert layer; and
coupling a first side of an atomic layer etching (ALE) etch layer to a second side of the hybrid SOT electrode-insert layer opposite the first side.

10. The method of claim 9, further comprising applying an interlayer dielectric (ILD) layer to edges of the MTJ, the SOT electrode and the ALE etch layers, wherein the ILD layer is in a plane substantially perpendicular to a plane of the MTJ, SOT electrode and etch layers.

11. The method of claim 10, further comprising etching the ALE etch layer using ALE until the SOT electrode-insert layer is exposed.

12. The method of claim 11, further comprising, after applying the ILD layer, planarizing a second side of the etch layer and a first edge of the ILD layer.

13. The method of claim 12, wherein planarizing further includes chemical mechanical processing (CMP).

14. The method of claim 12, further comprising coupling a first side of a SOT layer to the exposed SOT electrode-insert layer.

15. The method of claim 12, further comprising removing the ILD layer.

16. An apparatus comprising:
means for coupling a side of a magnetic free layer of a magnetic tunnel junction (MTJ) to a first side of a hybrid spin orbit torque (SOT) electrode-insert layer; and
means for coupling a first side of an atomic layer etching (ALE) etch layer to a second side of the hybrid SOT electrode-insert layer opposite the first side.

17. The apparatus of claim 16, further comprising means for applying an interlayer dielectric (ILD) layer to edges of the MTJ, the SOT electrode and the ALE etch layers, wherein the ILD layer is in a plane substantially perpendicular to a plane of the MTJ, SOT electrode and etch layers.

18. The apparatus of claim 17, further comprising means for etching the ALE etch layer using ALE until the SOT electrode-insert layer is exposed.

19. The apparatus of claim 18, further comprising means for planarizing a second side of the etch layer and a first edge of the ILD layer.

20. The apparatus of claim 19, further comprising coupling a first side of a SOT layer to the exposed SOT electrode-insert layer.
